(19) United States
(12) Patent Application Publication
(10) Pub. No.: US 2016/0204135 A1
(43) Pub. Date: Jul. 14, 2016

(54) THIN FILM TRANSISTOR ARRAY PANEL AND METHOD FOR MANUFACTURING THE SAME

(71) Applicant: Samsung Display Co., Ltd., Yongin-si (KR)

(72) Inventors: Hyung Min KIM, Yongin-si (KR); NAM JUNE KIM, Yongin-si (KR); Jae Hyoung YOUN, Hwaseong-si (KR); Jang Soo KIM, Asan-si (KR); Se Myung KWON, Asan-si (KR); Kang-Young LEE, Seongnam-si (KR)

(21) Appl. No.: 14/924,012

(22) Filed: Oct. 27, 2015

(30) Foreign Application Priority Data
Jan. 13, 2015 (KR) 10-2015-0006320

(51) Int. Cl. H01L 27/12; G02F 1/1368; G02F 1/1362; H01L 27/32

(52) U.S. Cl. CPC H01L 27/1225; H01L 27/124; H01L 27/3276; H01L 27/127; G02F 1/1368; G02F 1/136286

(57) ABSTRACT

A thin film transistor array panel according to an exemplary embodiment of the present invention includes: a gate line disposed on a substrate and including a gate electrode; a gate insulating layer formed on the gate line; a first oxide semiconductor layer disposed on the gate insulating layer and formed of an oxide semiconductor; a data wiring layer disposed on the gate insulating layer and including data line intersecting with the gate line, a source electrode connected to the data line, and a drain electrode facing the drain electrode; and a second oxide semiconductor layer covering the source electrode and the drain electrode, wherein the data wiring layer includes copper or a copper alloy.

### CLAIM OF PRIORITY

This application claims the priority to and all the benefits of Korean Patent Application No. 10-2015-0006320 filed in the Korean Intellectual Property Office (KIPO) on Jan. 13, 2015, the entire contents of which are incorporated herein by reference.

### BACKGROUND OF THE INVENTION

1. Field of the Invention

The present invention relates to a thin film transistor array panel and a method for manufacturing the same.

2. Description of the Related Art

Generally, a flat panel display such as a liquid crystal display or an organic light emitting device includes a plurality of pairs of field generating electrodes and an electro-optical active layer disposed therebetween. The liquid crystal display includes a liquid crystal layer as an electro-optical active layer, and the organic light emitting device includes an organic emission layer as an electro-optical active layer.

One of the pair of field generating electrodes is typically connected to a switching element to receive an electric signal, and the electro-optical active layer converts the electric signal into an optical signal and displays an image.

The flat panel display uses a thin film transistor (TFT) being a three-terminal element as a switching element, and includes signal lines, such as a gate line that transfers a scanning signal for controlling the thin film transistor (TFT) and a data line that transfers a signal to be applied to a pixel electrode.

Meanwhile, research has been conducted on an oxide semiconductor technology for realizing high-speed driving as an area of a display device increases and a method for reducing a resistance of a signal line. Particularly, in order to reduce the resistance of the signal line, a main wiring layer may be formed of a material such as copper or a copper alloy. However, at this time, there is a limitation in that the material such as copper is diffused into a semiconductor layer formed of an oxide semiconductor, thus reducing reliability of the device.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a thin film transistor array panel including an oxide semiconductor layer disposed between a main wiring layer and a passivation layer.

The present invention has been made in an effort to provide a method for manufacturing a thin film transistor array panel, including forming an oxide semiconductor layer on a main wiring layer.

An exemplary embodiment of the present invention provides a thin film transistor array panel including: a gate line disposed on a substrate and including a gate electrode; a gate insulating layer formed on the gate line; a first oxide semiconductor layer disposed on the gate insulating layer and formed of an oxide semiconductor; a data wiring layer disposed on the gate insulating layer and comprising a data line intersecting with the gate line, a source electrode connected to the data line, and a drain electrode facing the drain electrode; and a second oxide semiconductor layer covering the source electrode and the drain electrode, in which the data wiring layer includes copper or a copper alloy.

Each of side surfaces of the source electrode and the drain electrode may be exposed adjacent to a channel region of the second oxide semiconductor layer including a portion that is not covered with the source electrode and the drain electrode and is exposed between the source electrode and the drain electrode, and the second oxide semiconductor layer may cover the exposed side surfaces of the source electrode and the drain electrode.

The data wiring layer may include a barrier layer and a main wiring layer disposed on the barrier layer, the main wiring layer may include copper or a copper alloy, and the barrier layer may include metal oxide.

The passivation layer may contact the second oxide semiconductor layer covering the exposed side surfaces of the source electrode and the drain electrode.

The first oxide semiconductor layer may include at least one selected from zinc (Zn), indium (In), tin (Sn), gallium (Ga), and hafnium (Hf), and the second oxide semiconductor layer may include at least one selected from zinc (Zn), indium (In), tin (Sn), gallium (Ga), and hafnium (Hf).

The first oxide semiconductor layer and the second oxide semiconductor layer may be formed of the same material.

The first oxide semiconductor layer and the second oxide semiconductor layer may be indium-gallium-zinc oxide.

The gate insulating layer may include at least one selected from silicon oxide, silicon nitride, and silicon oxynitride.

The second oxide semiconductor layer may be formed only on the source electrode and the drain electrode.

The data wiring layer may include a capping layer disposed on the main wiring layer, and the capping layer includes metal oxide.

Another exemplary embodiment of the present invention provides a liquid crystal display including: a gate line disposed on a first substrate and including a gate electrode; a gate insulating layer formed on the gate line; a first oxide semiconductor layer disposed on the gate insulating layer and formed of an oxide semiconductor; a data wiring layer disposed on the gate insulating layer and comprising a data line intersecting with the gate line, a source electrode connected to the data line, and a drain electrode opposed to the drain electrode; a second oxide semiconductor layer covering the source electrode and the drain electrode; a pixel electrode contacting the drain electrode; a second substrate opposed to the first substrate; and a liquid crystal layer interposed between the first substrate and the second substrate, in which the data wiring layer includes copper or a copper alloy.

The second oxide semiconductor layer may be formed only on the source electrode and the drain electrode.

The first oxide semiconductor layer may include at least one selected from zinc (Zn), indium (In), tin (Sn), gallium (Ga), and hafnium (Hf), and the second oxide semiconductor layer may include at least one selected from zinc (Zn), indium (In), tin (Sn), gallium (Ga), and hafnium (Hf).

The first oxide semiconductor layer and the second oxide semiconductor layer may be formed of the same material.

Yet another exemplary embodiment of the present invention provides a method for manufacturing a thin film transistor array panel including: forming a gate line including a gate electrode on a substrate; forming a gate insulating layer on the gate line; forming a first oxide semiconductor layer including an oxide semiconductor on the gate insulating layer; forming a data wiring layer comprising a source electrode and a drain electrode on the first oxide semiconductor layer; forming a second oxide semiconductor layer on the source electrode and the drain electrode; and forming a passivation layer on the substrate comprising the second oxide semiconductor layer, in which the data wiring layer includes copper or a copper alloy.

The forming of the first oxide semiconductor layer and the forming of the data wiring layer may be simultaneously performed by using one mask.

The mask used in forming the second oxide semiconductor layer may be the same as the mask used in forming the data wiring layer.

The first oxide semiconductor layer may include at least one selected from zinc (Zn), indium (In), tin (Sn), gallium (Ga), and hafnium (Hf), and the second oxide semiconductor layer includes at least one selected from zinc (Zn), indium (In), tin (Sn), gallium (Ga), and hafnium (Hf).

The first oxide semiconductor layer and the second oxide semiconductor layer may be formed of the same material.

According to an exemplary embodiment of the present invention, since a structure that an additionally formed oxide semiconductor layer covers a portion of a main wiring layer exposed due to a process is included, it is possible to improve reliability by suppressing a material forming the main wiring layer from being oxidized. In addition, since a capping layer formed on the main wiring layer is omitted, process costs may be reduced.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a top plan view illustrating a thin film transistor array panel according to an exemplary embodiment of the present invention.

FIG. 2 is a cross-sectional view taken along line II-II of FIG. 1.

FIGS. 3 to 6 are cross-sectional views illustrating a method for manufacturing a thin film transistor array panel according to an exemplary embodiment of the present invention.

FIG. 7 is a cross-sectional view illustrating a thin film transistor array panel according to an exemplary embodiment of the present invention.

FIG. 8 is a photograph showing an interface between a main wiring layer and a passivation layer in a thin film transistor array panel according to comparative example.

FIG. 9 is a photograph showing an interface between a main wiring layer and a passivation layer in a thin film transistor array panel according to an exemplary embodiment of the present invention.

FIG. 10 is a cross-sectional view illustrating a liquid crystal display according to an exemplary embodiment of the present invention.

### DETAILED DESCRIPTION OF THE INVENTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereinafter, a thin film transistor array panel and a method for manufacturing the same according to an exemplary embodiment of the present invention will be described in detail with reference to the accompanying drawings.

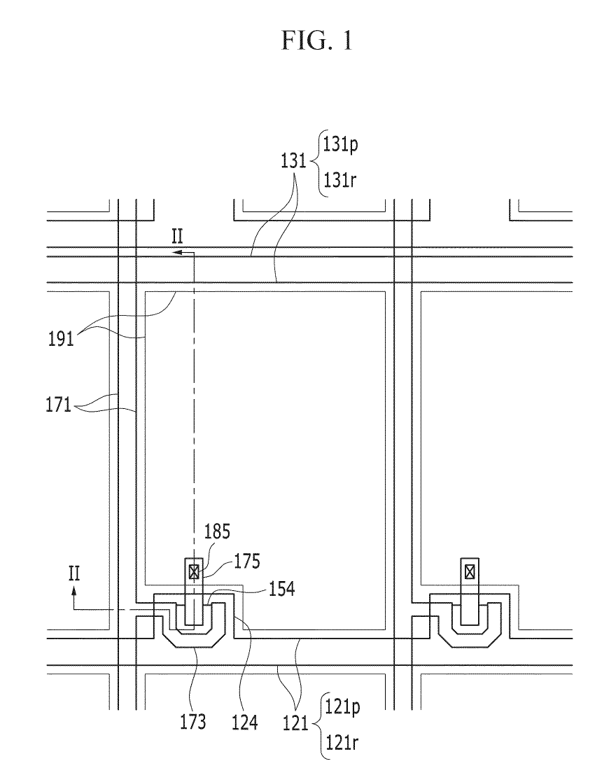

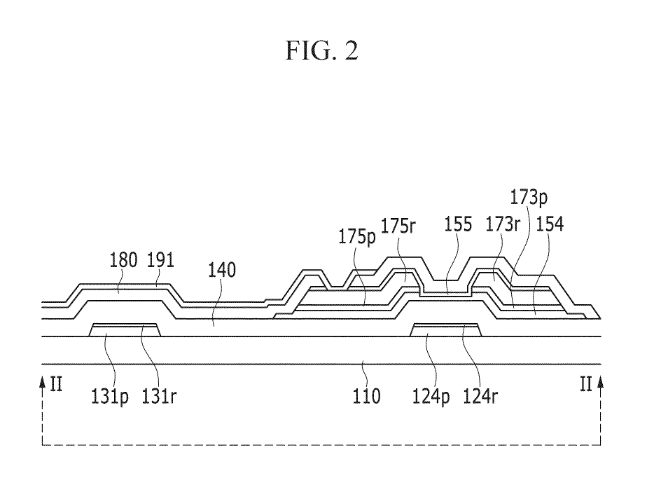

FIG. 1 is a top plan view illustrating a thin film transistor array panel according to an exemplary embodiment of the present invention. FIG. 2 is a cross-sectional view taken along line II-II′ of FIG. 1.

Referring to FIGS. 1 and 2, the thin film transistor array panel 100 according to the exemplary embodiment includes a plurality of gate lines 121 formed on an insulation substrate 110 made of transparent glass, plastic, or the like.

The gate lines 121 transfer a gate signal and extend in a substantially horizontal direction. Each of the gate lines 121 includes a plurality of gate electrodes 124 protruding from the gate lines 121.

The gate line 121 and gate electrode 124 may have a dual-layer structure including a first layer 121p and a second layer 121r. Each of the first layer 121p and the second layer 121r may be formed of aluminum (Al), an aluminum-based metal such as an aluminum alloy, silver (Ag), a silver-based metal such as a silver alloy, a copper (Cu), a copper-based metal such as a copper alloy, molybdenum (Mo), a molybdenum-based metal such as a molybdenum alloy, chromium (Cr), titanium (Ti), tantalum (Ta), manganese (Mn), or the like. For example, the first layer 121p may include titanium, and the second layer 121r may include copper or a copper alloy.

Also, the first layer 121p and the second layer 121r may be formed by combining layers that have different physical properties. In the present exemplary embodiment, it has been described that the gate line 121 and the gate electrode 124 are formed in a dual-layer, but the exemplary embodiment is not limited thereto. The gate line 121 and the gate electrode 124 may be formed in a single-layer or a triple-layer.

A storage electrode line 131 is disposed in parallel to the gate line 121. The storage electrode line 131 may be formed in parallel to the gate line 121 across a pixel area.

The storage electrode line may also have a dual-layer structure including a first layer 131p and a second layer 131r.

Each of the first layer 131p and the second layer 131r may be formed of aluminum (Al), an aluminum-based metal such as an aluminum alloy, silver (Ag), a silver-based metal such as a silver alloy, a copper (Cu), a copper-based metal such as a copper alloy, molybdenum (Mo), a molybdenum-based metal such as a molybdenum alloy, chromium (Cr), titanium (Ti), tantalum (Ta), manganese (Mn), or the like. For example, the first layer 131p may include titanium, and the second layer 131r may include copper or a copper alloy.

The storage electrode line 131 may be firmed in the same process as the gate line 121, and materials constituting the storage electrode line 131 and the gate line 121 may be the same material.

A gate insulating layer 140 formed of an insulating material such as silicon oxide or silicon nitride is disposed on the gate line 121 and the storage electrode line 131. The gate insulating layer 140 may have a multilayer structure that includes at least two insulating layers having different physical properties.

A plurality of semiconductor layers 154, which are formed of an oxide semiconductor, are formed on the gate insulating layer 140. The semiconductor layers 154 extend in a substantially vertical direction, and include a plurality of projections 154 extending toward the gate electrode 124.

The semiconductor layer 154 includes at least one selected from zinc (Zn), indium (In), tin (Sn), gallium (Ga), and hafnium (Hf). Particularly, in the present exemplary embodiment, the semiconductor layer 154 may be indium-gallium-zinc oxide.

That is, the semiconductor layer 154 may be formed of an oxide semiconductor, and in the present invention, the “semiconductor layer 154” may be used interchangeably with the term “first oxide semiconductor layer 154”.

A plurality of data lines 171, a plurality of source electrodes 173 connected to the data lines 171, and a plurality of drain electrodes 175 are formed on the semiconductor layer 154 and the gate insulating layer 140.

The data lines 171 transfer a data signal, and extend in a substantially vertical direction to interest with the gate lines 121. The source electrodes 173 may extend from the data lines 171, overlap the gate electrode 124, and have a substantially U-shape.

The drain electrodes 175 are separated from the data lines 171 and extend upward from a center portion of the U-shape of the source electrodes 173.

The data line 171, the source electrode 173, and the drain electrode 175 have a dual-layer structure including lower barrier layers 171p, 173p, and 175p, and main wiring layers 171r, 173r, and 175r. The lower barrier layers 171p, 173p, and 175p are formed of metal oxide, and the main wiring layers 171r, 173r, and 175r are formed of copper or a copper alloy.

Specifically, the lower barrier layers 171p, 173p, and 175p may be formed of one of indium-zinc oxide, gallium-zinc oxide, and aluminum-zinc oxide.

The lower barrier layers 171p, 173p, and 175p function as a diffusion prevention layer preventing a material such as copper from being diffused into the semiconductor layer 154.

An oxide semiconductor layer 155 is disposed on the main wiring layers 171r, 173r, and 175r. The oxide semiconductor layer 155 will be referred to as a second oxide semiconductor layer 155 so as to distinguish from an oxide semiconductor layer constituting the semiconductor layer 154 formed under the source electrode 173 and the drain electrode 175.

The second oxide semiconductor layer 155 directly contacts surfaces of the source electrode 173 and the drain electrode 175, covers the source electrode 173 and the drain electrode 175, and particularly, covers exposed side surfaces (A) of the source electrode 173 and the drain electrode 175. Furthermore, the second oxide semiconductor layer 155 also is formed on the projection 154 of the semiconductor layer 154. That is, as shown in FIG. 2, the second oxide semiconductor layer 155 may also be formed on an exposed region of the first oxide semiconductor 154 between the source electrode 173 and the drain electrode 175 and contact the first oxide semiconductor layer 154.

The second oxide semiconductor layer 155 includes at least one selected from zinc (Zn), indium (In), tin (Sn), gallium (Ga), and hafnium (Hf). Particularly, in the present exemplary embodiment, the second oxide semiconductor layer 155 may be indium-gallium-zinc oxide.

That is, the first oxide semiconductor layer 154 and the second oxide semiconductor layer 155 may be formed of the same material. Both of the first oxide semiconductor layer 154 and the second oxide semiconductor layer 155 may be indium-gallium-zinc oxide.

However, a material of the second oxide semiconductor layer 155 may be different from a material of the first oxide semiconductor layer 154. That is, any material may be used for the second oxide semiconductor layer 155 as long as the material is a transparent conducting oxide that reduces a carrier concentration by increasing oxygen content.

Hereinafter, the exposed regions (A) of the source electrode 173 and the drain electrode 175 will be described in detail.

Referring to FIG. 2, an exposed portion, which is not covered with the data line 171 and the drain electrode 175, exists between the source electrode 173 and the drain electrode 175 in the projection 154 of the first oxide semiconductor layer 154. The first oxide semiconductor layer 154 may have the substantially same plane pattern as the data line 175 and the drain electrode 175 except for the exposed region of the projection 154.

One gate electrode 124, one source electrode 173, and one drain electrode 175 form one thin film transistor (TFT) together with the projection 154 of the first oxide semiconductor layer 154, and a channel region of the thin film transistor (TFT) is formed on the projection 154 between the source electrode 173 and the drain electrode 175.

Side surfaces of the source electrode 173 and the drain electrode 175 adjacent to the channel region are exposed, and the exposed side surfaces (A) of the source electrode 173 and the drain electrode 175 are covered with the second oxide semiconductor layer 155. When the exposed side surfaces of the source electrode 173 and the drain electrode 175 contact a passivation layer including silicon oxide that is formed through a subsequent process without the second oxide semiconductor layer 155, or are heat-treated so as to have a channel characteristic, materials such as copper included main wiring layers 171r, 173r, and 175r may form oxide and thus be diffused into the channel region. In the present exemplary embodiment, the second oxide semiconductor layer 155 may prevent the materials such as copper from being oxidized.

In the present exemplary embodiment, since the second oxide semiconductor layer 155 is formed by using the same mask as that used in forming the source electrode 173 and the drain electrode 175, a separate mask process is not required.

Typically, a capping layer also is formed on the main wiring layers 171r, 173r, and 175r as a diffusion prevention layer. However, in the thin film transistor array panel according to the present exemplary embodiment, since the second oxide semiconductor layer 155 is formed, the formation of a separate capping layer may be omitted. Therefore, sputtering costs required for forming the capping layer may be reduced, and productivity may be improved.

A passivation layer 180 is formed on the second oxide semiconductor layer 155. The passivation layer 180 is formed of an inorganic insulating material such as silicon nitride or silicon oxide, an organic insulating material, or a low permittivity insulating material.

A plurality of contact holes 185 exposing one end of the drain electrode 175 are formed on the passivation layer 180.

In the present exemplary embodiment, the passivation layer 180 may be formed in a dual-layer structure including a lower passivation layer and an upper passivation layer. The lower passivation layer may be formed of silicon oxide, and the upper passivation layer may be formed of silicon nitride. In the present exemplary embodiment, since the semiconductor layer 154 includes an oxide semiconductor, it is desirable that the lower passivation layer adjacent to the semiconductor layer 154 be formed of silicon oxide. When the lower passivation layer is formed of silicon nitride, a characteristic of a thin film transistor does not appear.

A plurality of pixel electrodes 191 are formed on the passivation layer 180. The pixel electrodes 191 are physically and electrically connected to the drain electrodes 175 through the contact holes 185, and receive data voltages from the drain electrodes 175.

The pixel electrode 191 may be made of a transparent conductor such as ITO or IZO.

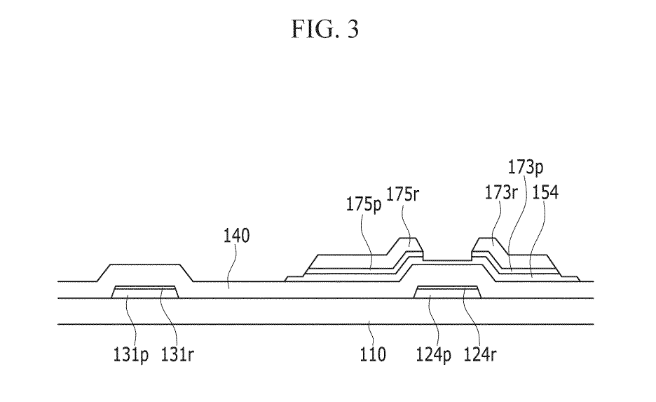

Hereinafter, a method for manufacturing a thin film transistor array panel according to an exemplary embodiment of the present invention will be described with reference to FIGS. 3 to 6.

FIGS. 3 to 6 are cross-sectional views illustrating a method for manufacturing a thin film transistor array panel according to an exemplary embodiment of the present invention. FIGS. 3 to 6 are views sequentially illustrating a cross-section taken along II-IF of FIG. 1.

Referring to FIG. 3, a gate line 121 including a gate electrode 124 and a storage electrode line 131 are formed by stacking at least one selected from molybdenum (Mo), a molybdenum-based metal such as a molybdenum alloy, chromium (Cr), a chromium alloy, titanium (Ti), a titanium alloy, tantalum (Ta), a tantalum alloy, manganese (Mn), and a manganese alloy on an insulation substrate 110 formed of transparent glass or plastic, stacking one selected from aluminum (Al), an aluminum-based material such as an aluminum alloy, silver, a silver-based material such as a silver alloy, copper (Cu), and a copper-based alloy such as a copper alloy thereon to thereby form a double-layer, and then patterning the double-layer. For example, lower layers 121p, 124p, and 131p may include titanium, and upper layers 121r, 124r, and 131r may include copper or a copper alloy.

Specifically, after forming the double-layer, a photosensitive film (not shown) is stacked and patterned, and then the lower layers 121p, 124p, and 131p, and the upper layers 121r, 124r, and 131 are etched together by using the patterned photosensitive film (not shown) as a mask. An etchant capable of etching the lower layer 121p, 124p, and 131p, and the upper layers 121r, 124r, and 131 together may be used as an etchant used in etching.

Next, a gate insulating layer 140 is stacked on the gate line 121, the gate electrode 124, and the storage electrode line 131.

The gate insulating layer 140 may be formed by depositing a first insulating layer (not shown) including silicon nitride, and then depositing a second insulating layer (not shown) including silicon oxide.

After that, as shown in FIG. 2, a first oxide semiconductor layer 154, a source electrode 173, and a drain electrode 175 are formed by stacking and patterning the first oxide semiconductor layer 154, the lower barrier layers 171p, 173p, and 175p, and the main wiring layers 171r, 173r, and 175r.

The first oxide semiconductor layer 154 may be formed so as to include at least one selected from zinc (Zn), indium (In), tin (Sn), gallium (Ga), and hafnium (Hf), the lower barrier layers 171p, 173p, and 175p may be formed so as to include at least one selected from indium-zinc oxide, gallium-zinc oxide, and aluminum-zinc oxide, and the main wiring layers 171r, 173r, and 175r may be formed so as to include copper or a copper alloy.

At this time, after stacking the first oxide semiconductor layer 154, the lower barrier layers 171p, 173p, and 175p, and the main wiring layers 171r, 173r, and 175r, a channel region of the first oxide semiconductor layer 154 may be formed by using photosensitive film patterns having different thicknesses for each region. That is, in order to form the first oxide semiconductor layer 154 exposed between the source electrode 173 and the drain electrode 175, a photosensitive film pattern on the channel region in which the first oxide semiconductor layer 154 is exposed may be smaller than other regions.

When photosensitive film patterns having different thickness are used, the first oxide semiconductor layers 154 and 154, which have the same plane pattern as the lower layers 171p, 173p, and 175p of the data line 171, the source electrode 173, and the drain electrode 175, are formed. Meanwhile, the first oxide semiconductor layers 154 and 154 may have the substantially same plane pattern as the data line 171, the source electrode 173, and the drain electrode 175, except for a portion exposed between the drain electrode 175 and the source electrode 173.

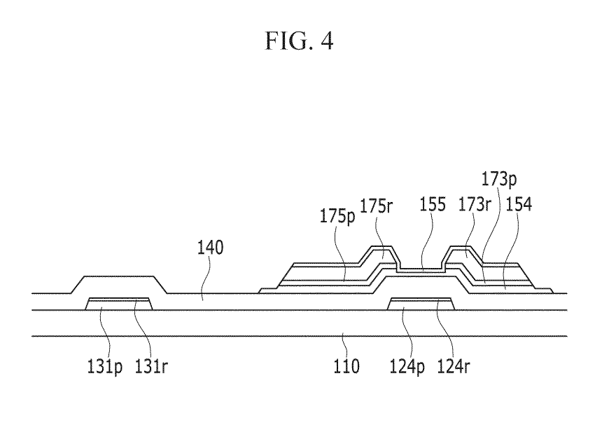

Next, referring to FIG. 4, a second oxide semiconductor layer 155 is formed on the source electrode 173, the drain electrode 175, and the exposed first oxide semiconductor layer 154. The second oxide semiconductor layer 155 is formed along surfaces of the source electrode 173 and the drain electrode 175. At this time, a side surface of each of the source electrode 173 and the drain electrode 175, which is adjacent to a channel region of a projection 154 of the first oxide semiconductor layer 154 including an exposed portion that is not covered with the source electrode 173 and the drain electrode 175 is exposed between the source electrode 173 and the drain electrode 175. In addition, the second oxide semiconductor layer 155 is formed so as to cover the exposed side surfaces of the source electrode 173 and the drain electrode 175.

At this time, the second oxide semiconductor layer 155 may be formed by using the same mask as the aforementioned mask used in forming the source electrode 173 and the drain electrode 175.

At this time, the second oxide semiconductor layer 155 may include at least one selected from zinc (Zn), indium (In), tin (Sn), gallium (Ga), and hafnium (Hf). The second oxide semiconductor layer 155 may be formed of the same material as the first oxide semiconductor layer 154.

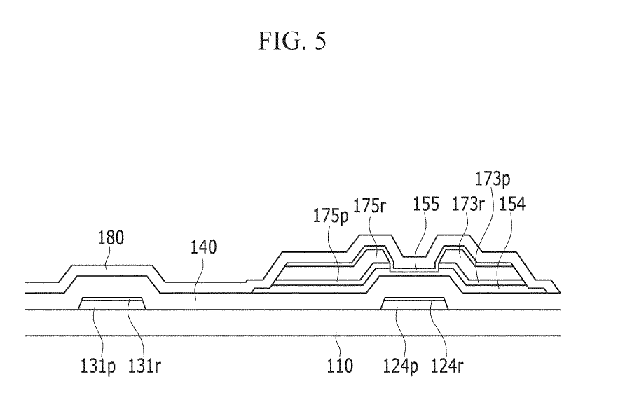

Next, referring to FIG. 5, a passivation layer 180 is formed on the second oxide semiconductor layer 155. The passivation layer 180 may be formed by forming a lower passivation layer (not shown) including silicon oxide on the second oxide semiconductor layer 155 and forming an upper passivation layer (not shown) including silicon nitride on the lower passivation layer.

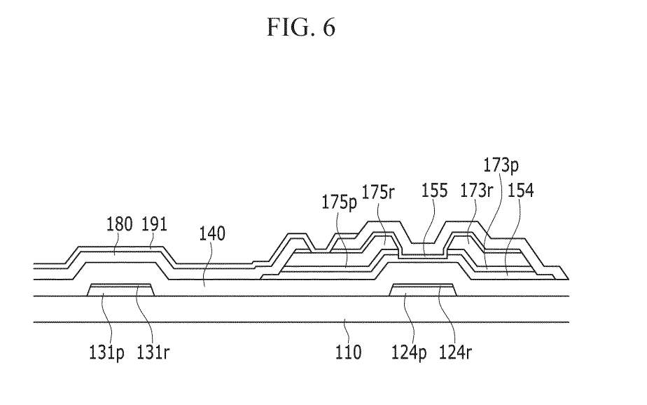

After that, as shown in FIG. 6, a contact hole 185 exposing a portion of the drain electrode 15 may be formed by patterning the passivation layer 180, and a thin film transistor array panel as illustrated in FIG. 2 may be formed by forming a pixel electrode 191 on the passivation layer 180. At this time, the pixel electrode 191 is formed so as to be physically connected to the drain electrode 175 through the contact hole 185.

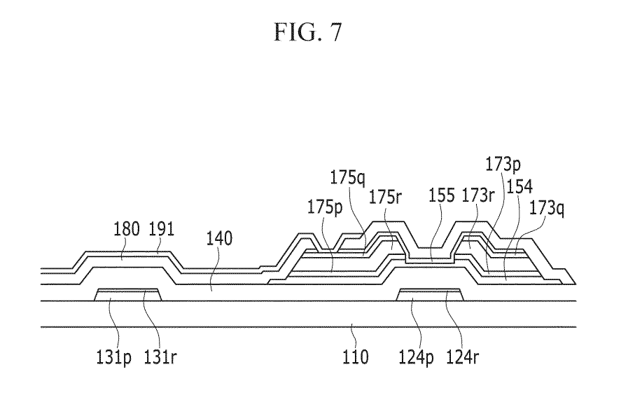

FIG. 7 is a cross-sectional view illustrating a thin film transistor array panel according to an exemplary embodiment of the present invention.

An exemplary embodiment shown in FIG. 7 is substantially identical to the exemplary embodiment shown in FIG. 2.

However, in the thin film transistor array panel according to the exemplary embodiment of FIG. 7, capping layers 171q, 173q, and 175q are formed on main wiring layers 171r, 173r, and 175r of the source electrode 173 and the drain electrode 175. The capping layer may be formed so as to include one of indium-zinc oxide, gallium-zinc oxide, and aluminum-zinc oxide.

The thin film transistor array panel according to the exemplary embodiment of FIG. 7 has a structure in which all of the capping layers 173q and 175q, and the second oxide semiconductor layer 155 are formed in order to prevent materials such as copper forming the source electrode 173 and the drain electrode 175 from forming oxide and being diffused into the channel region.

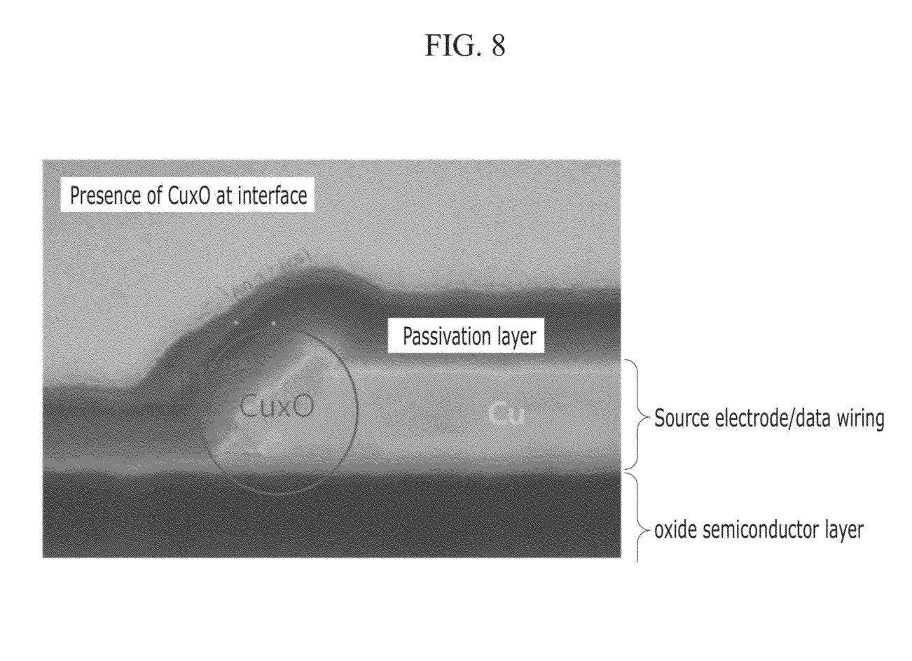

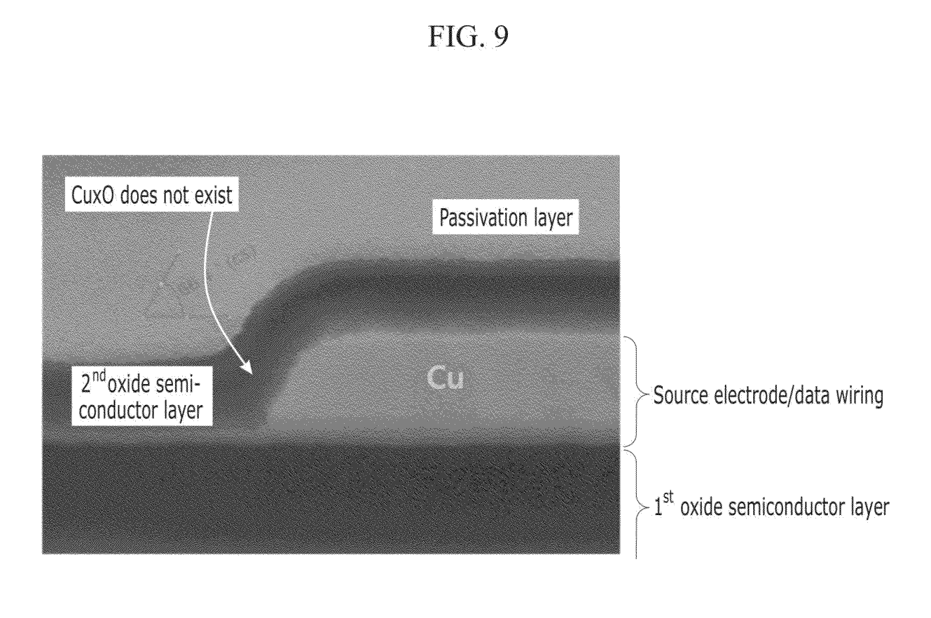

FIG. 8 is a photograph showing an interface between a main wiring layer and a passivation layer in a thin film transistor array panel according to the present invention and comparative example. FIG. 9 is a photograph showing an interface between a main wiring layer and a passivation layer in a thin film transistor array panel according to an exemplary embodiment of the present invention.

Referring to FIG. 8, it may be confirmed that copper oxide such as CuₓO is formed in an interface between a main wiring layer including copper and a passivation layer. That is, in the thin film transistor array panel according to comparative example, in which side surfaces of the source electrode and the drain electrode are not protected by the second oxide semiconductor layer 155, copper oxide is formed in an interface of the source electrode, the drain electrode, and the passivation layer by the diffusion of copper forming the source electrode and the drain electrode.

When copper oxide is formed, voids are formed in the source electrode and drain electrode due to copper diffused therefrom, and the channel region on which a semiconductor is disposed is contaminated with copper oxide. This causes the quality deterioration of the thin film transistor array panel.

However, in the thin film transistor array panel according to the exemplary embodiment of the present invention, exposed side surfaces and top surfaces of the source electrode and the drain electrode are protected by the second oxide semiconductor layer 155. Accordingly, a copper material included in the source electrode and the drain electrode is not diffused into the passivation layer, and thus, copper oxide is not formed in the channel region. Therefore, as shown in FIG. 9, copper oxide is not formed between the main wiring layer and the passivation layer.

Therefore, the contamination of the channel region may be prevented, and the formation of voids in the source electrode and the drain electrode caused by the diffusion of copper may be prevented.

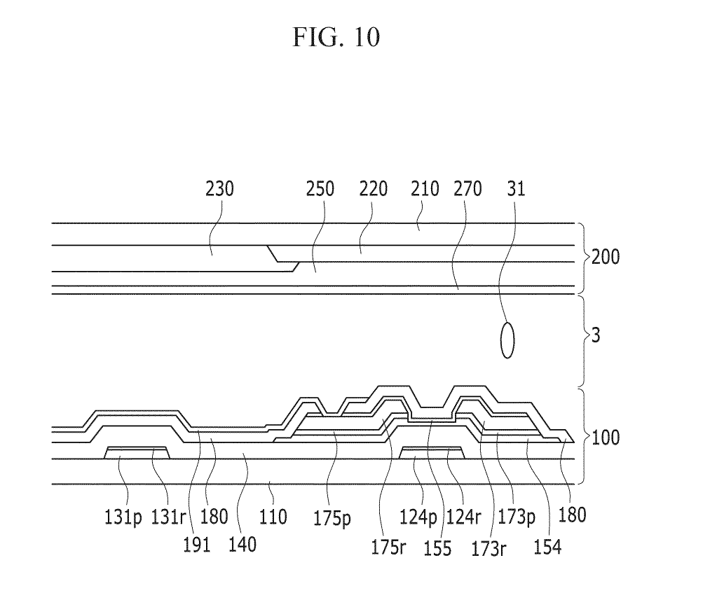

FIG. 10 is a cross-sectional view illustrating a liquid crystal display according to an exemplary embodiment of the present invention.

Referring to FIG. 10, a second substrate 210 is disposed at a position facing a first substrate 110. The second substrate 210 may be an insulation substrate made of transparent glass or plastic. A light blocking member 220 is formed on the second substrate 210. The light blocking member 220 is referred to as a black matrix, and blocks light leakage.

A plurality of color filters 230 are formed on the second substrate 210 and the light blocking member 220. The color filters 230 may mostly exist on a region surrounded by the light blocking member 220, and may lengthily extend along a row of pixel electrodes 191. Each color filter 230 may display one of primary colors such as three primary colors of red, green, and blue. However, each color filter 230 may display, but is not limited to three primary colors of red, green, and blue, one of cyan, magenta, yellow, and white.

It is described that the light blocking member 220 and the color filter 230 are formed on the opposed display panel 200, but at least one from selected from the light blocking member 220 and the color filter 230 may be formed on the thin film transistor array panel 100.

An overcoat 250 is formed on the color filter 230 and the light blocking member 220. The overcoat 250 may be made of an insulating material, prevent the color filter 230 from being exposed, and provide a flat surface. The overcoat 250 may be omitted.

A common electrode 270 is formed on the overcoat 250.

A pixel electrode 191 receiving data voltage and a common electrode 170 receiving voltage generates an electric field together to determine a direction of crystal molecules 31 of a liquid crystal layer 3 therebetween. The pixel electrode 191 and the common electrode 270 forms a capacitor to maintain received voltage even after the thin film transistor is turned off.

The pixel electrode 191 may overlap a storage electrode line (not shown) to form a storage capacitor, and thus reinforce the voltage maintenance performance of the liquid crystal capacitor.

Contents of an exemplary embodiment described with reference to FIG. 2 may be applied to a description of the thin film transistor array panel 100.

Here, that the case where the thin film transistor array panel according to the present exemplary embodiment is applied to the liquid crystal display has been described, but the thin film transistor array panel according to the present exemplary embodiment may be widely applied to organic light emitting displays and other displays performing a switching operation by using a thin film transistor.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

### DESCRIPTION OF SYMBOLS

121: Gate line
124: Gate electrode
131: Storage electrode line
140: Passivation layer
154: First oxide semiconductor layer
155: Second oxide semiconductor layer
171 Data line
173 Source electrode
175: Drain electrode
180: Passivation layer
191: Pixel electrode

What is claimed is:

1. A thin film transistor array panel comprising:
a gate line disposed on a substrate and including a gate electrode;
a gate insulating layer formed on the gate line;
a first oxide semiconductor layer disposed on the gate insulating layer and formed of an oxide semiconductor;
a data wiring layer disposed on the gate insulating layer and comprising a data line intersecting with the gate line, a source electrode connected to the data line, and a drain electrode facing the drain electrode; and
a second oxide semiconductor layer covering the source electrode and the drain electrode,
wherein the data wiring layer includes copper or a copper alloy.

2. The thin film transistor array panel of claim 1, wherein:
each of side surfaces of the source electrode and the drain electrode is exposed adjacent to a channel region of the second oxide semiconductor layer including a portion that is not covered with the source electrode and the drain electrode and is exposed between the source electrode and the drain electrode, and the second oxide semiconductor layer covers the exposed side surfaces of the source electrode and the drain electrode.

3. The thin film transistor array panel of claim 2, wherein:
the data wiring layer comprises a barrier layer and a main wiring layer disposed on the barrier layer, the main wiring layer includes copper or a copper alloy, and the barrier layer includes metal oxide.

4. The thin film transistor array panel of claim 3, wherein:
the passivation layer contacts the second oxide semiconductor layer covering the exposed side surfaces of the source electrode and the drain electrode.

5. The thin film transistor array panel of claim 1, wherein:
the first oxide semiconductor layer includes at least one selected from zinc (Zn), indium (In), tin (Sn), gallium (Ga), and hafnium (Hf), and
the second oxide semiconductor layer includes at least one selected from zinc (Zn), indium (In), tin (Sn), gallium (Ga), and hafnium (Hf).

6. The thin film transistor array panel of claim 1, wherein:
the first oxide semiconductor layer and the second oxide semiconductor layer are formed of the same material.

7. The thin film transistor array panel of claim 6, wherein:
the first oxide semiconductor layer and the second oxide semiconductor layer are indium-gallium-zinc oxide.

8. The thin film transistor array panel of claim 1, wherein:
the gate insulating layer includes at least one selected from silicon oxide, silicon nitride, and silicon oxynitride.

9. The thin film transistor array panel of claim 1, wherein:
the second oxide semiconductor layer is formed only on the source electrode and the drain electrode.

10. The thin film transistor array panel of claim 2, wherein:
the data wiring layer comprises a capping layer disposed on the main wiring layer, and
the capping layer includes metal oxide.

11. A liquid crystal display comprising:
a gate line disposed on a first substrate and including a gate electrode;
a gate insulating layer formed on the gate line;
a first oxide semiconductor layer disposed on the gate insulating layer and formed of an oxide semiconductor;
a data wiring layer disposed on the gate insulating layer and comprising a data line intersecting with the gate line, a source electrode connected to the data line, and a drain electrode opposed to the drain electrode;
a second oxide semiconductor layer covering the source electrode and the drain electrode;
a pixel electrode contacting the drain electrode;
a second substrate opposed to the first substrate; and
a liquid crystal layer interposed between the first substrate and the second substrate,
wherein the data wiring layer includes copper or a copper alloy.

12. The liquid crystal display of claim 11, wherein:
the second oxide semiconductor layer is formed only on the source electrode and the drain electrode.

13. The liquid crystal display of claim 11, wherein:
the first oxide semiconductor layer includes at least one selected from zinc (Zn), indium (In), tin (Sn), gallium (Ga), and hafnium (Hf), and
the second oxide semiconductor layer includes at least one selected from zinc (Zn), indium (In), tin (Sn), gallium (Ga), and hafnium (Hf).

14. The liquid crystal display of claim 11, wherein:
the first oxide semiconductor layer and the second oxide semiconductor layer are formed of the same material.

15. A method for manufacturing a thin film transistor array panel, the method comprising:
forming a gate line including a gate electrode on a substrate;
forming a gate insulating layer on the gate line;
forming a first oxide semiconductor layer including an oxide semiconductor on the gate insulating layer;
forming a data wiring layer comprising a source electrode and a drain electrode on the first oxide semiconductor layer;
forming a second oxide semiconductor layer on the source electrode and the drain electrode; and
forming a passivation layer on the substrate comprising the second oxide semiconductor layer,
wherein the data wiring layer includes copper or a copper alloy.

16. The method of claim 15, wherein:
the forming of the first oxide semiconductor layer and the forming of the data wiring layer are simultaneously performed by using one mask.

17. The method of claim 16, wherein:
the mask used in forming the second oxide semiconductor layer is the same as the mask used in forming the data wiring layer.

18. The method of claim 15, wherein:
the first oxide semiconductor layer includes at least one selected from zinc (Zn), indium (In), tin (Sn), gallium (Ga), and hafnium (Hf), and
the second oxide semiconductor layer includes at least one selected from zinc (Zn), indium (In), tin (Sn), gallium (Ga), and hafnium (Hf).

19. The method of claim 15, wherein:
the first oxide semiconductor layer and the second oxide semiconductor layer are formed of the same material.
